(19) United States
(12) Patent Application Publication
(10) Pub. No.: US 2025/0369153 A1
(43) Pub. Date: Dec. 4, 2025

(54) METHOD FOR MANUFACTURING GROUP III NITRIDE SEMICONDUCTOR

(71) Applicants: TOYODA GOSEI CO., LTD., Kiyosu-shi (JP); The University of Osaka, Osaka (JP)

(72) Inventors: Kazuyoshi IIDA, Kiyosu-shi (JP); Shinya ASAMI, Kiyosu-shi (JP); Taku FUJIMORI, Kiyosu-shi (JP); Seiji NAGAI, Kiyosu-shi (JP); Miki MORIYAMA, Kiyosu-shi (JP); Yusuke MORI, Osaka (JP); Masayuki IMANISHI, Osaka (JP); Shigeyoshi USAMI, Osaka (JP)

(21) Appl. No.: 19/222,679

(22) Filed: May 29, 2025

(30) Foreign Application Priority Data
Jun. 4, 2024 (JP) 2024-090957
Jun. 4, 2024 (JP) 2024-090958
Oct. 15, 2024 (JP) 2024-180347

(51) Int. Cl. C30B 19/12; C30B 19/02; C30B 29/40

(52) U.S. Cl. CPC C30B 19/12; C30B 19/02; C30B 29/403

(57) ABSTRACT

A method for manufacturing a group III nitride semiconductor, the method including a crystal growing step of growing the group III nitride semiconductor on a seed substrate by supplying a gas containing nitrogen into a mixed melt in which a group III metal and a flux are mixed. The seed substrate includes a substrate and a plurality of seed crystals provided on the substrate and including the group III nitride semiconductor, and the seed crystals each include a (10-11) plane on an outer peripheral surface thereof.

### CROSS-REFERENCE

This application claims priorities to Japanese Patent Application Nos. 2024-090958 filed on Jun. 4, 2024, 2024-090957 filed on Jun. 4, 2024, and 2024-180347 filed on Oct. 15, 2024, the contents of which are fully incorporated herein by reference.

### BACKGROUND

### Technical Field

The present disclosure relates to a method for manufacturing a group III nitride semiconductor.

### Background Art

As a method for manufacturing gallium nitride (GaN), a Na flux method is known. In the Na flux method, nitrogen is dissolved in a mixed melt of gallium (Ga) and sodium (Na) to thereby grow GaN in a liquid phase. In general, the Na flux method grows GaN on a seed substrate by placing the seed substrate in the mixed melt.

As a means for growing a large-area GaN crystal with low dislocation density and low warpage when adopting the Na flux method, it is known to use a multi-point seed (MPS) substrate as the seed substrate. The MPS substrate has a number of small dot-shaped seed crystals periodically arranged on a substrate of, for example, sapphire.

JP-A-2019-151519 has a description that a contour of the seed crystals in an MPS substrate is made to be circular or hexagonal in a plan view.

### SUMMARY

However, when the seed crystals are formed in the shape of a circle or hexagon in a plan view as described in JP-A-2019-151519, an initial nucleus that grows from each seed crystal cannot be shaped stably without any variation. Thus, it has not been possible to form GaN uniformly.

The present disclosure has been made in view of the above and aims to provide a method for manufacturing a group III nitride semiconductor and a seed substrate.

One aspect of this disclosure is a method for manufacturing a group III nitride semiconductor, the method comprising:
a crystal growing step of growing the group III nitride semiconductor on a seed substrate by supplying a gas containing nitrogen into a mixed melt in which a group III metal and a flux are mixed, wherein
the seed substrate includes a substrate and a plurality of seed crystals provided on the substrate and composed of the group III nitride semiconductor, and
the seed crystals each include a (10-11) plane on an outer peripheral surface thereof.

Another aspect of this disclosure is a seed substrate comprising:
a substrate; and
a plurality of seed crystals provided on the substrate and composed of a group III nitride semiconductor, wherein
the seed crystals each include a (10-11) plane on an outer peripheral surface thereof.

In the above-described aspect, the seed crystals each include the (10-11) plane on the outer peripheral surface thereof. In such a configuration, variation in the shape of the initial nuclei can be curtailed.

As mentioned above, according to the above aspect, a method for manufacturing a group III nitride semiconductor and a seed substrate in which the variation in the shape of the initial nuclei can be curtailed can be provided.

### BRIEF DESCRIPTION OF THE DRAWINGS

FIG. 1 is a cross-sectional view of a seed substrate showing a configuration of a first embodiment, of which the cross-section is perpendicular to a principal surface of a substrate.

FIG. 2 is a plan view showing a configuration of the seed substrate according to the first embodiment.

FIG. 3 is a cross-sectional view showing a configuration of a seed crystal, of which the cross-section is perpendicular to the principal surface of the substrate.

FIG. 4 is a plan view showing the configuration of the seed crystal.

FIG. 5 is a flowchart showing production steps of a group III nitride semiconductor in the first embodiment.

FIGS. 6A through 6C are Illustrations showing a production process of a group III nitride semiconductor in the first embodiment.

FIG. 7 is an illustration showing a Flux Film Coating (FFC) method.

FIG. 8 is an SEM image of the seed crystal obliquely viewed from above.

FIG. 9 is an enlarged SEM image of the seed crystal.

FIG. 10 is an SEM image showing a cross-section of the seed crystal.

FIGS. 11A and 11B are SEM images of initial nuclei obliquely viewed from above.

FIG. 12 is a fluorescence X-ray image of a grown crystal.

FIG. 13A is a cross-sectional view showing the configuration of a seed crystal according to a modification 1 from the first embodiment, of which the cross-section is perpendicular to the principal surface of the substrate.

FIG. 13B is a plan view showing the configuration of the seed crystal according to the modification 1 from the first embodiment.

FIG. 14A is a cross-sectional view showing the configuration of a seed crystal according to a modification 2 from the first embodiment, of which the cross-section is perpendicular to the principal surface of the substrate.

FIG. 14B is a plan view showing the configuration of the seed crystal according to the modification 2 from the first embodiment.

FIG. 15A is a cross-sectional view showing the configuration of a seed crystal according to a modification 3 from the first embodiment, of which the cross-section is perpendicular to the principal surface of the substrate.

FIG. 15B is a plan view showing the configuration of the seed crystal according to the modification 3 from the first embodiment.

FIG. 16A is a cross-sectional view showing the configuration of a seed crystal according to a modification 4 from the first embodiment, of which the cross-section is perpendicular to the principal surface of the substrate.

FIG. 16B is a plan view showing the configuration of the seed crystal according to the modification 4 from the first embodiment.

FIG. 17A is a cross-sectional view showing the configuration of a seed crystal according to a modification 5 from the first embodiment, of which the cross-section is perpendicular to the principal surface of the substrate.

FIG. 17B is a plan view showing the configuration of the seed crystal according to the modification 5 from the first embodiment.

FIG. 18 is a cross-sectional view showing a configuration of the seed crystal, of which the cross-section is perpendicular to a principal surface of the substrate.

FIG. 19 is a flowchart showing production steps of a group III nitride semiconductor in the second embodiment.

FIG. 20 is a cross-sectional view showing a configuration of the seed crystal according to the second embodiment, of which the cross-section is perpendicular to a principal surface of the substrate.

FIG. 21 is a cross-sectional view showing a configuration of the seed crystal according to the second embodiment, of which the cross-section is perpendicular to a principal surface of the substrate.

A method for manufacturing a group III nitride semiconductor comprises a crystal growing step of growing the group III nitride semiconductor on a seed substrate by supplying a gas containing nitrogen into a mixed melt in which a group III metal and a flux are mixed, wherein the seed substrate includes a substrate and a plurality of seed crystals provided on the substrate and composed of the group III nitride semiconductor, and the seed crystals each include a (10-11) plate on a side thereof.

In this manufacturing method for a group III nitride semiconductor, the outer peripheral surface of the seed crystal may have a plurality of the (10-11) planes and a ridge line formed between the (10-11) planes adjacent to each other. Such a configuration makes it possible to curtail variation in the shape of initial nuclei more effectively.

In this manufacturing method, the outer peripheral surface of the seed crystal may be composed of only the (10-11) planes and the ridge lines. Such a configuration makes it possible to curtail variation in the shape of initial nuclei more effectively.

In this manufacturing method, a height of the seed crystal may be 0.01 times or more and 0.6 times or less of a diameter of the seed crystal in a plan view, and/or may be 30 μm or more. Such a configuration can make it easier to grow an initial nucleus from the outer peripheral surface of the seed crystal.

In this manufacturing method, the diameter of the seed crystal may be 10 μm or more and 500 μm or less in a plan view.

In this manufacturing method, the seed crystal may have a truncated regular hexagonal pyramid portion shaped in a form of a truncated regular hexagonal pyramid. Such a configuration makes it possible to curtail variation in the shape of initial nuclei more effectively. In addition, the seed substrate may include a disk portion having a diameter smaller than a diameter of the truncated regular hexagonal pyramid portion, which is located between the substrate and the truncated regular hexagonal pyramid portion. The disk portion makes it possible to disperse the stress caused by separation of the substrate completely grown and prevent any cracks from forming in the grown crystals.

In this manufacturing method, the seed crystals each may have a recess at a center thereof. Such a configuration can curtail upward propagation of dislocation of the seed crystals. Such a configuration can curtail upward propagation of dislocation in the seed crystals.

In this manufacturing method, the recess may have a depth reaching the substrate.

In this manufacturing method, a diameter of the recess may be set such that the seed crystals each have a shape with no upper surface.

In this manufacturing method, the recess may have irregularities on a side surface thereof.

In this manufacturing method, a mask with an opening may be formed on the substrate to selectively grow the group III nitride semiconductor through the opening, thereby forming the seed crystals. Such a configuration makes it possible to uniformly shape the seed crystals.

In this manufacturing method, the recess of the seed crystal may have a depth not reaching the substrate, and the method further may further comprise a melt-back step prior to the crystal growing step, in which a degree of supersaturation of nitrogen in the mixed melt is set lower compared to a degree of supersaturation for crystal growth in the group III nitride semiconductor, and the seed substrate is poured into the mixed melt thus prepared to thereby cause melt-back to a bottom surface of the recess of each seed crystal.

In this manufacturing method, in the melt-back step, melt-back may be caused to at least a partial region on the bottom surface of the recess of the seed crystal to an extent of exposing the substrate.

In this manufacturing method, in the melt-back step, the melt-back may be caused to a whole region on the bottom surface of the recess of the seed crystal to an extent of exposing the substrate.

In this manufacturing method, in the melt-back step, a plurality of pits may be formed on the bottom surface of the recess of the seed crystal, and the substrate may be exposed to the bottom surface of the pits.

A seed substrate comprises a substrate; and a plurality of seed crystals provided on the substrate and composed of a group III nitride semiconductor, and the seed crystals each include a (10-11) plane on an outer peripheral surface thereof.

In this seed substrate, the outer peripheral surface of the seed crystal may be composed of only a plurality of (10-11) planes and ridge lines. Such a configuration makes it possible to curtail variation in the shape of initial nuclei more effectively.

In this seed substrate, the outer peripheral surface of the seed crystal may be composed of only the (10-11) planes. Such a configuration makes it possible to curtail variation in the shape of initial nuclei more effectively.

In this seed substrate, a height of the seed crystal may be 0.01 times or more and 0.6 times or less of a diameter of the seed crystal in a plan view and/or may be 30 μm or more. Such a configuration can make it easier to grow an initial nucleus from the outer peripheral surface of the seed crystal.

In this seed substrate, the diameter of the seed crystal may be 10 μm or more and 500 μm or less in a plan view.

In this seed substrate, the seed crystal may have a truncated regular hexagonal pyramid portion shaped in a form of a truncated regular hexagonal pyramid. In addition, the seed substrate may include a disk portion having a diameter smaller than a diameter of the truncated regular hexagonal pyramid portion, which is located between the substrate and the truncated regular hexagonal pyramid portion. The disk portion makes it possible to disperse the stress caused by separation of the substrate completely grown and prevent any cracks from forming in the grown crystals.

In this seed substrate, the seed crystals each may have a recess at a center thereof. Such a configuration can curtail upward propagation of dislocation in the seed crystals.

In this seed substrate, the recess may have a depth reaching the substrate.

In this seed substrate, a diameter of the recess may be set such that the seed crystals each have a shape with no upper surface.

In this seed substrate, the recess may have irregularities on a side surface thereof.

### First Embodiment

### 1. Outline of Flux Method

A first embodiment is a method for manufacturing a group III nitride semiconductor, which uses the flux method to grow a group III nitride semiconductor. The flux method is a method for growing a group III nitride semiconductor epitaxially in the liquid phase by dissolving a mixed melt that contains an alkali metal that acts as a flux and a III group metal as a raw material while supplying a gas containing nitrogen to the mixed melt

The III group metal as a raw material includes at least one of gallium (Ga), aluminum (Al), and indium (In). A group III nitride semiconductor to be grown can be controlled in composition depending on the ratio of these metals. For example, GaN, AlN, InN, AlGaN, InGaN, AlGaInN, etc. can be grown. This disclosure is particularly suitable for growing GaN.

As the alkali metal acting as a flux, sodium (Na) is usually used. However, potassium (K) or a mixture of Na and K can also be used. In addition, Lithium (Li) and alkaline earth metals can be mixed therein.

Carbon (C) may be added into the mixed melt. Addition of C makes it possible to facilitate the growth of the crystal. In addition, any dopants other than carbon may be added to the mixed melt for the purpose of controlling the physical properties such as conductivity and magnetism of the group III nitride semiconductor to be grown, promoting crystal growth, preventing the growth of polycrystal, and controlling the growth direction. For example, germanium (Ge) can be used as an n-type dopant, and magnesium (Mg), zinc (Zn), and calcium (Ca) can be used as p-type dopants.

The gas containing nitrogen may be a gas of nitrogen molecules or a gas of a compound containing nitrogen such as ammonia as a constituent element, and may also be a mixture of these gases or a mixture of the gas containing nitrogen and any inert gas such as a rare gas.

### 2. Structure of Seed Substrate

In the first embodiment, a seed substrate 9 is placed in the mixed melt to grow a group III nitride semiconductor on the seed substrate 9. Although the seed substrate 9 may be placed in the mixed melt before heated and pressurized, it is preferably placed in the mixed melt after heated and pressurized until the growth temperature and growth pressure are reached. This can prevent a seed crystal 2 on the seed substrate 9 from melting back.

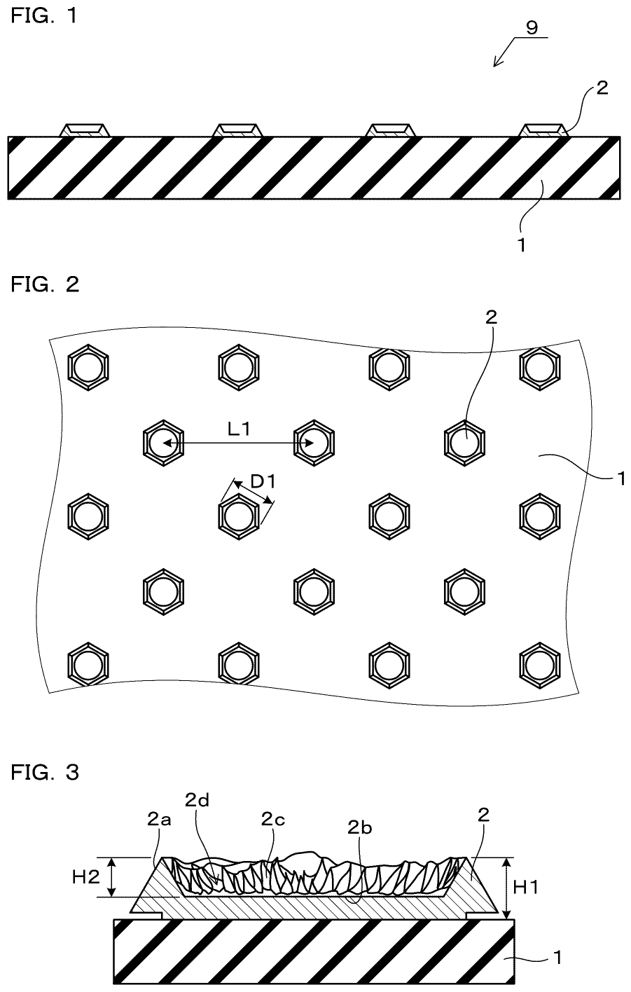

An MPS (multipoint seed) substrate is used for the seed substrate 9. The MPS substrate is a substrate with a plurality of dot-shaped seed crystals 2 arranged periodically on the substrate 1. FIG. 1 is a cross-sectional view of the seed substrate 9, of which the cross-section is perpendicular to a principal surface of the substrate. FIG. 2 is a plan view of the seed substrate 9 viewed from above.

The substrate 1 can be made of a group III nitride semiconductor, sapphire, aluminum oxynitride, SiC, Si, spinel, ZnO, gallium oxide, etc. In the case of a sapphire substrate, for example, the principal surface is c-plane or a-plane.

On the substrate 1, a plurality of the seed crystals 2 are provided via a buffer layer (not shown). The seed crystals 2 are arranged in a triangular lattice pattern. A buffer layer and the seed crystals 2 are made of a group III nitride semiconductor having any composition such as GaN, AlGaN, and AlN. An appropriate material is selected for the buffer layer depending on the material of the seed crystals 2. For example, in the case where the seed crystals 2 are made of GaN, GaN is preferably selected for the buffer layer. The material for the seed crystal 2 usually has the same composition as a group III nitride semiconductor intended to grow by the flux method. Although the seed crystals 2 may be grown using any method, such as MOCVD, HVPE, or MBE, MOCVD and HVPE are preferable in terms of crystallinity and growth time.

The arrangement of the seed crystals 2 is a regular triangular lattice pattern as shown in FIG. 2. The arrangement is not limited to a regular triangular lattice pattern and any periodic arrangement is possible. A pattern with high symmetry, such as a square lattice pattern or a regular triangular lattice pattern is preferable. Such a configuration makes it possible to uniformly combine a group III nitride semiconductors grown from various types of the seed crystal 2 to thereby grow a group III nitride semiconductor with fewer dislocations and warping. In the case of the regular triangular lattice pattern, the direction of the arranging is preferably aligned with the a-axis or m-axis of the seed crystal 2. Here, alignment does not mean a perfect match, and an angular deviation of around 10 degrees falls within a tolerance range. The angular deviation is preferably less than 1 degree.

The distance L1 between the centers of the seed crystals 2 adjacent to each other is preferably 100 to 2000 μm. This range makes it possible to grow a group III nitride semiconductor with fewer dislocations and warping. The range is more preferably 200 to 1500 μm, and even more preferably 300 to 1000 μm.

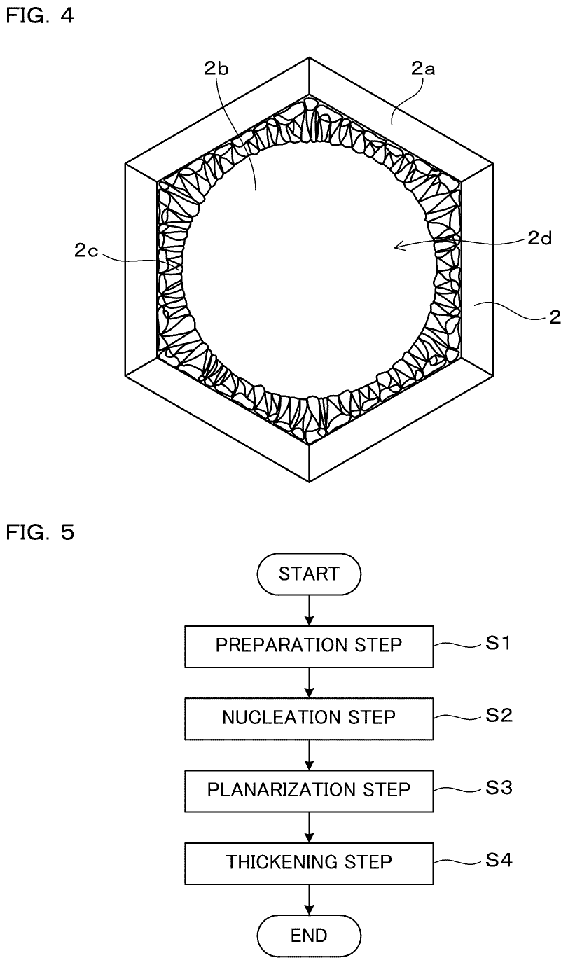

Next, the shape of the seed crystal 2 will be described in detail. FIG. 3 is a cross-sectional view showing a configuration of the seed crystal 2, of which the cross-section is perpendicular to the principal surface of the substrate. FIG. 4 is a plan view showing the configuration of the seed crystal 2. As shown in FIGS. 3 and 4, the seed crystal 2 has a shape including a truncated regular hexagonal pyramid portion provided with a recess 2d at its center. In addition, there is provided a disk portion having a diameter smaller than a diameter of the truncated regular hexagonal pyramid portion between the substrate 1 and the truncated regular hexagonal pyramid portion.

As described below, the seed crystal 2 is formed by selective growth using a mask with an opening, and through which the crystal is grown laterally. The opening of the mask has a circular pattern. Therefore, after the mask is removed, the opening of the mask patterns the substrate in a form of a circular disk. The patterned part corresponds to the disk portion.

The disk portion has the same shape as the opening of the mask for selectively growing the seed crystal 2. Therefore, the thickness of the disk is approximately equal to the thickness of the mask. The diameter of the disk portion is approximately equal to the diameter of the mask opening. A diameter D1 of the truncated regular hexagonal pyramid portion is larger than the diameter of the disk portion. The disk portion is a circle in a plan view, and thus the stress caused when the substrate 1 is separated after group III nitride semiconductors have been grown using the flux method can be dispersed to thereby curtail occurrence of any cracks in the grown crystal.

Although the disk portion can be replaced with a regular hexagonal plate shaped in a form of a regular hexagon or otherwise by changing the opening pattern of the mask, a circular form of the disk portion is preferred as it disperses stress as described above.

The bottom surface of the truncated regular hexagonal pyramid portion of the seed crystal has a shape of a regular hexagon. In particular, a regular hexagon with each side aligned with the m-plane of the seed crystal 2 (with each side aligned with the a-axis direction) is preferred because a group III nitride semiconductor is hexagonal, and a regular hexagon allows a group III nitride semiconductor grown from the truncated regular hexagonal pyramid portion of each seed crystal 2 to coalesce uniformly. However, it is not necessary for each side of the regular hexagon to be perfectly aligned with the a-axis, and an angular misalignment of about 10 degrees is acceptable. Preferably, the angular misalignment is 1 degree or less.

Each of the six outer peripheral surfaces 2a of the truncated regular hexagonal pyramid portion of the seed crystal 2 has a specific face orientation of a group III nitride semiconductor crystal, which is the (10-11) plane of a group III nitride semiconductor. The (10-11) plane is stable in the mixed melt in the Na-flux method. Therefore, the group III nitride semiconductor grows from the outer peripheral surface 2a of the truncated regular hexagonal pyramid portion of the seed crystal 2 while maintaining the (10-11) plane(s). As a result, the shape of the initial crystals 3 can be uniformly shaped. The surface of the outer peripheral surface 2a need not be entirely a (10-11) surface, but at least 95% of the entire outer peripheral surface is preferably a (10-11) surface. It is noted that the (10-11) plane referred to here also includes a plane that forms an angle of −5 to 5 degrees with respect to the (10-11) plane as an error.

The diameter D1 (a diameter of the circumscribed circle in a plan view) of the truncated regular hexagonal pyramid portion of the seed crystal 2 is preferably 10 to 500 μm. In this range, a group III nitride semiconductor with fewer dislocations and warpage can be grown. In addition, the area of the outer peripheral surface 2a of the truncated regular hexagonal pyramid portion of the seed crystal 2 can be made larger to thereby facilitate the growth of an initial nucleus 3 from the outer peripheral surface 2a. The diameter D1 is more preferably 50 to 300 μm, and even more preferably 100 to 200 μm.

Additionally, a height H1 of the seed crystal 2 is preferably 30 μm or more. Within this range, the outer peripheral surface 2a can have a sufficiently wide area, which enables uniform crystal growth from the outer peripheral surface 2a. As a result, the shapes of the initial nuclei 3 growing from the seed crystals 2 can be uniformly shaped. However, if the H1 is excessively high, there is such a problem that it takes much time to form the seed crystals 2. Thus, the H1 is preferably set to t 100 μm or less. More preferably, it is 20 to 60 μm, and even more preferably, 30 to 50 μm.

Furthermore, for the same reasons as above, the height H1 of the seed crystal 2 is preferably 0.01 to 0.6 times the diameter D1 of the seed crystal 2. More preferably, it is 0.1 to 0.35 times, and even more preferably, it is 0.15 to 0.3 times.

A recess 2d is provided at the center of the seed crystal 2. By providing the recess 2d, the initial nucleus 3 grown from the seed crystal 2 does not fill the recess 2d to form a void 7. The void 7 thus formed prevents dislocations in the seed crystal 2 from propagating upward, which enables growth of a high-quality group III nitride semiconductor.

The bottom surface 2b of the recess 2d is flat and corresponds to a (0001) plane (c-plane) of a group III nitride semiconductor. The bottom surface 2b is approximately circular when viewed in plan. It is noted that the bottom surface 2b does not necessarily need to be flat and may have irregularities. Additionally, the shape of the bottom surface 2b does not necessarily need to be circular when viewed in plan.

The side surface 2c of the recess 2d has a lot of irregularities formed thereon and wholly has the same level of inclination as that of the (10-11) plane. By shaping the side surface 2c to have such irregularities, the side surface 2c serves as a starting point for crystal growth of the group III nitride semiconductor to thereby make it easy to fill the upper portion of the seed crystal 2 with the group III nitride semiconductor. It is noted that the side surface 2c may also be a flat surface.

A depth H2 of the recess 2d is preferably 10 to 100 μm. Within this range, it becomes easier to form voids 7, and thus a higher-quality group III nitride semiconductors can be grown. More preferably, the depth H2 is 20 to 60 μm, and even more preferably, 30 to 50 μm. For the same reasons, the depth H2 of the recess 2d is preferably 0.3 to 1.0 times the height H1 of the seed crystal 2, and more preferably 0.6 to 0.8 times.

The diameter of the top surface of the recess 2d falls within the range such that the seed crystal 2 has no upper surface. The side surface 2c of the recess 2d and the outer peripheral surface 2a of the seed crystal 2 are connected at an angle. Therefore, there is no c-plane on the top of the seed crystal 2. c-plane may be etched in the mixed melt in the Na-flux method, which is a factor of causing variation in the shape of each initial nucleus 3. In addition, dislocations in the seed crystal 2 may be propagated upward by crystal growth from the c-plane. Therefore, if the top of the crystal is shaped to have no c-plane, variation in the shape of each initial nucleus 3 can be curtailed, and dislocation in the seed crystal 2 can be prevented from propagating upward.

### 3. Method of Preparing Seed Substrate

The seed substrate 9 can be prepared, for example, as follows. First, a mask with a plurality of openings is formed on the substrate 1. The openings are arranged in an equilateral triangular lattice pattern. The shape of each opening is a circle. Although shapes other than a circle, such as regular hexagons, are also acceptable, a circle is preferable as used in the embodiment in order to form a disc portion and curtail cracking caused when the substrate is separated. The material of the mask can be any material that can prevent a group III nitride semiconductor from growing on the mask, such as SiO₂.

Next, a buffer layer (not shown) and the seed crystal 2 are selectively grown on the substrate exposed to the opening in sequence by MOCVD, HVPE, or other methods. Next, the mask is removed by wet etching with hydrofluoric acid or the like. The seed substrate 9 can be prepared as described above.

Here, by appropriately controlling the growth conditions when selectively growing the seed crystal 2 through the opening of the mask, facet growth of a group III nitride semiconductors is made possible, so that the seed crystal 2 can be shaped as shown in FIG. 3 and FIG. 4. For example, the growth temperature may be 1120 to 1145° C. and the V/III ratio may be 970 to 1020. The seed crystals 2 can be uniformly shaped because the selective growth determines the shape of each seed crystal 2.

### 4. Method of Manufacturing Group III Nitride Semiconductor

Next, the method of manufacturing a group III nitride semiconductor in the first embodiment will be explained with reference to FIGS. 5 to 7. FIG. 5 is a flowchart showing the production steps of a group III nitride semiconductor in the first embodiment. As shown in FIG. 5, the manufacturing method of a group III nitride semiconductor in the first embodiment includes a preparation step S1, a nucleation step S2, a planarization step S3, and a thickening step S4.

### 4-1. Preparation Step

First, the preparation step S1 is performed. The preparation step S1 is as follows.

First, the furnace atmosphere is replaced with an inert gas, the furnace is heated, and then vacuumed to sufficiently reduce outgas components in the furnace, such as oxygen.

Next, a predetermined amount of an alkali metal and a group III metal are weighed in a glove box in which the atmosphere, such as oxygen and dew point, is controlled. The weighed predetermined amount of the alkali metal and the group III metal are then fed into a crucible 100. If necessary, additive elements such as carbon may be fed.

Next, the crucible 100 in which the raw materials are set and the seed substrate 9 are placed in the reaction vessel and evacuated, and then a gas containing nitrogen is supplied to the reaction vessel.

Once the pressure in the reaction vessel reaches a crystal growth pressure, the furnace is heated to a crystal growth temperature. The crystal growth temperature is, for example, 700° C. or higher and 1000° C. or lower, and the crystal growth pressure is, for example, 2 MPa or higher and 10 MPa or lower. In the process of raising the temperature, the solid alkali metal and solid group III metal in the crucible 100 melt and turn into liquid, forming a mixed melt 101. In this stage, the seed substrate 9 is not yet put into the mixed melt 101.

### 4-2. Nucleation Step

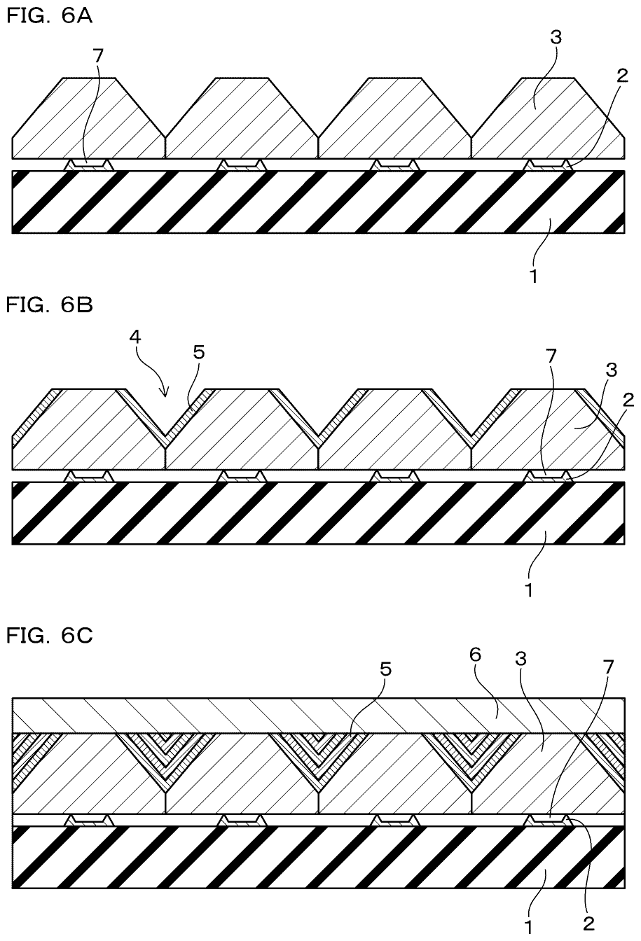

When the temperature and pressure inside the reaction vessel reach the crystal growth temperature and the crystal growth pressure, and the degree of supersaturation of the nitrogen dissolved in the mixed melt 101 exceeds a predetermined value, the nucleation step S2 is performed. In the nucleation step S2, an initial nucleus 3 is formed on the seed crystal 2. In the nucleation step S2, first, the seed substrate 9 is put into the mixed melt 101 in the crucible 100. Since the inside of the reaction vessel has been at the crystal growth temperature and pressure and the supersaturation of nitrogen dissolved in the mixed melt 101 has reached the predetermined value, group III nitride semiconductor crystals (initial nuclei 3) are grown from the crystals 2 of the seed substrate 9. The initial nuclei 3 grow until adjacent initial nuclei 3 begin to coalesce with each other (see FIG. 6A). A gap remains between the initial nuclei 3 and the substrate 1.

Here, the (10-11) plane, which is the outer peripheral surface 2a of the truncated regular hexagonal pyramid portion of the seed crystal 2, is stable in the mixed melt 101 without being etched. In addition, the height H1 of the seed crystal 2 is 30 μm or more, and the outer peripheral surface 2a is sufficiently large in area. Therefore, the initial nucleus 3 grows from the outer peripheral surface 2a while maintaining the (10-11) plane. Because the initial nucleus 3 grows from the seed crystal 2, which is uniformly shaped, while maintaining the (10-11) plane, variation in the shape of each initial nucleus 3 can be curtailed and the initial nuclei 3 can be uniformly shaped.

Because the recess 2d is formed in the center of the seed crystal 2, the initial nucleus 3 does not fill the recess 2d completely to form a void 7. The void 7 keeps in the mixed melt 101. Because the void 7 is formed at the upper part of the seed crystal 2, dislocations in the seed crystal 2 are prevented from being succeeded upward.

Furthermore, by setting the diameter of the recess 2d large, the seed crystal 2 is formed into a shape that has no upper surface (c-plane). The c-plane may be etched in the mixed melt 101 and is an unstable surface. Because crystal growth from such an unstable surface does not occur, variation in the shape of the initial nucleus 3 can be further curtailed. Additionally, because crystal growth from the c-plane does not occur, the transfer of dislocations from the seed crystal 2 to the upper part can be further curtailed.

### 4-3. Planarization Step

When the initial nuclei 3 adjacent to each other begin to coalesce, the planarization step S3 is performed. In the planarization step S3, the spaces between the seed crystals 2 to bring up a flat crystal. In the planarization step S3, the crystal is grown using the FFC (flux film coating) method.

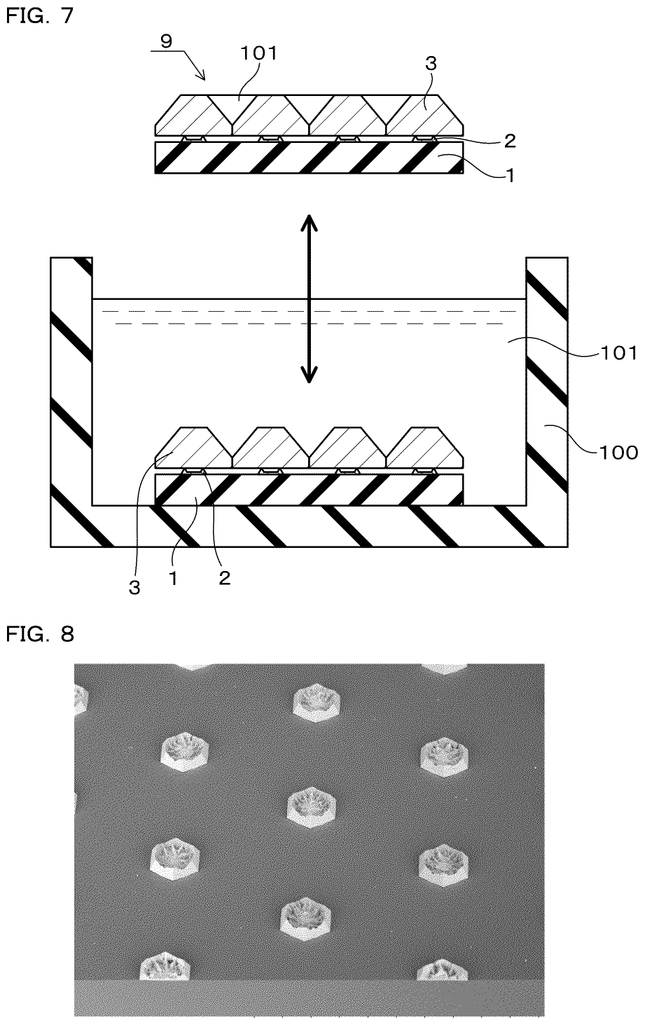

The FFC method involves repeatedly removing the seed substrate 9 from the mixed melt 101 and then reintroducing it into the mixed melt 101 at predetermined intervals (see FIG. 7). At the stage where the adjacent initial nuclei 3 begin to coalesce, the depression 4 is formed on the coalescent surfaces. When the seed substrate 9 is removed from the mixed melt 101, the mixed melt 101 accumulates in the depressions 4 between the adjacent initial nuclei 3. This allows the crystals 5 to grow along the depressions 4 (see FIG. 6B).

Here, because the mixed melt 101 accumulated in the depression 4 is thin in thickness, nitrogen tends to supersaturate. Thus, the crystal growth rate can be accelerated. However, because the amount of the accumulated mixed melt 101 is small, the amount of the group III metal is also low, so that the crystal growth is caused to cease after some time. To address this, the seed substrate 9 is reintroduced into the mixed melt 101, and the substrate is removed from the mixed melt 101 to thereby intermittently supply the mixed melt 101 containing the group III metal to the depression 4. The FFC method is continued until the depression 4 is filled by growth of the crystal 5. This enables the growth of crystals with a flat c-plane.

Although the FFC growth process is not necessarily needed, it is preferable to perform the FFC growth process to further improve crystal flatness and reduce warpage.

### 4-4. Thickening Step

Once the depression 4 is filled to form a flat crystal surface, the thickening step S4 is performed. In the thickening step S4, the flattened crystal is grown thicker. First, in the thickening step S4, the seed substrate 9 is put into the mixed melt 101 again. Then, the crystal 6 of the group III nitride semiconductor is grown to be thickened (see FIG. 6C). Because the shape of the initial nuclei 3 is uniform, the crystal 6 can also be formed uniformly in the plane. In addition, because the transfer of dislocations from the seed crystal 2 to the upper part is curtailed, the crystals 6 can be formed with high quality.

Once the crystals 6 has grown to the intended thickness, the temperature is lowered to room temperature and the pressure is also lowered to ambient pressure to finish growing the group III nitride semiconductor. Here, the gap between the initial nucleus 3 and the substrate 1 remains unfilled. Therefore, the substrate 1 can be spontaneously separated due to the difference in thermal expansion coefficients during temperature dropping.

According to the manufacturing a group III nitride semiconductor in the first embodiment described above, the outer periphery surface of the seed crystal 2 is composed of (10-11) planes. Therefore, the variation in the shape of the initial nuclei 3 can be curtailed, and uniform, high-quality crystals 6 can be grown.

In addition, in this embodiment, the seed crystal 2 is provided with the recess 2d in the center and with no upper surface. Therefore, during the growth of the initial nucleus 3, the top of the seed crystal 2 is not filled and the voids 7 are formed. As a result, the upward propagation of dislocations in the seed crystal 2 can be curtailed, which enables high-quality crystals 6 to be grown.

Next, the experimental results on the first embodiment will be described.

### Experiment 1

A mask made of SiO₂ was formed on the substrate 1 composed of c-plane sapphire by CVD method. The mask had a pattern of circular openings arranged in an equilateral triangular lattice. The distance between the centers of adjacent openings was 550 μm, and the diameter of the openings was 175 μm. Next, a buffer layer was formed on the bottom of the openings by the MOCVD method, and the seed crystal 2 made of GaN was subsequently formed on the buffer layer at a growth temperature of 1140° C. and a V/III ratio of 720.

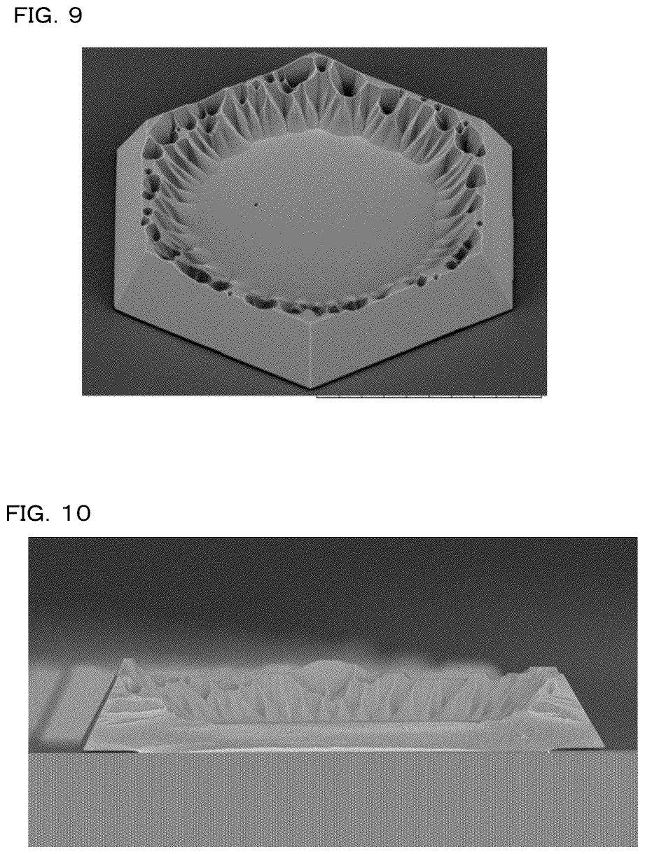

FIG. 8 is an SEM image of the seed crystals 2 on the substrate 1, and FIG. 9 is an enlarged SEM image of the seed crystal 2. FIG. 10 is a cross-sectional SEM image of the seed crystal 2. As shown FIGS. 8 to 10, the seed crystal 2 has a disk portion located on the substrate 1 in contact therewith and a truncated regular hexagonal pyramid portion located on the disk portion in contact therewith and having the recess 2d in the center, and six outer peripheral surfaces 2a of the truncated regular hexagonal pyramid portion are visible. The angles of the outer peripheral surfaces 2a identify the outer peripheral surfaces 2a to be (10-11) planes. The diameter of the recess 2d is wide, and the side surface 2c of the recess 2d and the outer peripheral surface 2a of the seed crystal 2 form a vertex angle. It can be seen that the shape has no upper surface accordingly. It can also be seen that the side surface 2c of the recess 2d has a lot of irregularities. It can also be seen from FIG. 7 that the seed crystals 2 are shaped uniformly and evenly.

### Experiment 2

A GaN crystal was grown by the Na-flux method using the seed substrate 9 prepared as the similar way as in Experiment 1. The growth was carried out to the extent that the initial nucleus 3 grown from the seed crystal 2 coalesced with the initial nucleus 3 grown from the seed crystal 2 adjacent thereto.

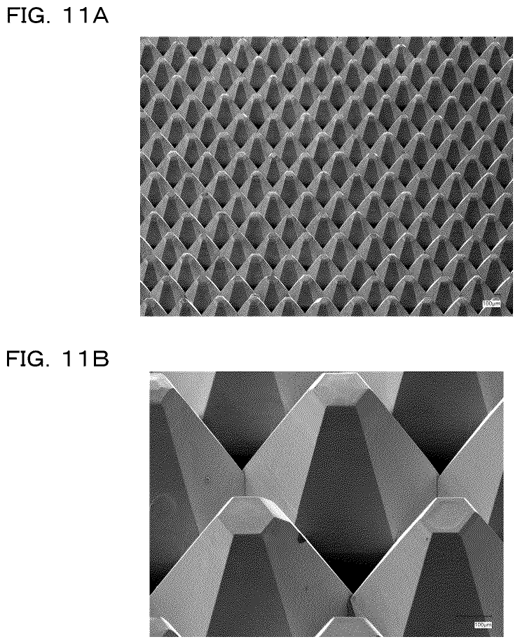

FIG. 11A is an SEM image of the grown initial nuclei 3, and FIG. 11B is an enlarged SEM image. As shown in FIGS. 11A and 11B, the initial nucleus 3 has a shape of a truncated regular hexagonal pyramid with (10-11) planes on the outer peripheral surface and (0001) plane (c-plane) on the top. In addition, as shown in FIGS. 11A and 11B, each initial nucleus 3 grown from each seed crystal 2 is uniform in shape. Therefore, it can be seen that the initial nuclei 3 can be coalesced uniformly to thereby grow flat and uniform crystals 6 on the initial nuclei 3.

### Experiment 3

A GaN crystal was grown by the Na-flux method using the seed substrate 9 prepared as the similar way as in Experiment 1. The growth was carried out by the FFC method to fill the depressions 4 between the initial nuclei 3 when the initial nuclei 3 grown from the seed crystals 2 coalesced with each other, and to grow the crystals 6 on the coalesced initial nuclei 3.

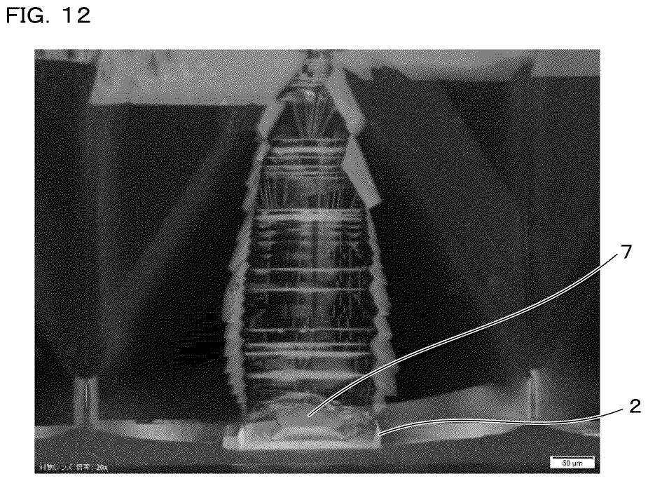

FIG. 12 is a fluorescent X-ray image of a cross section of the seed substrate 9 after GaN crystals have grown, and is a fluorescent image of the position where oxygen is present. FIG. 12 shows that the recess 2d in the seed crystal 2 is not filled by the initial nucleus 3 and the void 7 is formed. In the void 7, the mixed melt (containing mainly sodium and gallium) to be used in the Na-flux method is kept in. Thus, it can be seen that the seed substrate 9 in the first embodiment can form the void 7 to thereby prevent the upward propagation of dislocations in the seed crystal 2.

### First Modification of the First Embodiment

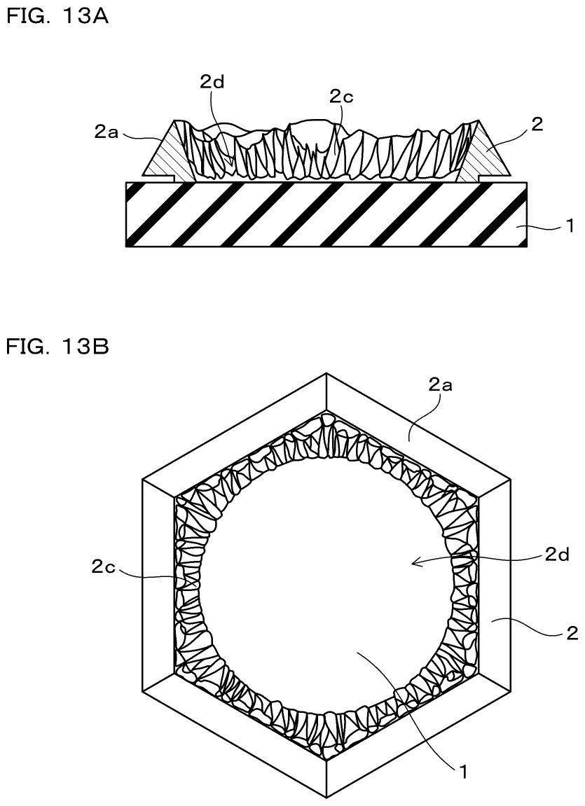

In the first embodiment, the depth of the recess 2d of the seed crystal 2 was set to the extent that the substrate 1 is not exposed, however, as shown in FIGS. 13A and 13B, the depth of the recess 2d may be set to the depth that can expose the substrate 1 at the bottom. FIGS. 13A and 13B show the shape of seed crystal 2 in the first modification of the first embodiment. FIG. 13A is a cross-sectional view perpendicular to the principal surface of the substrate, and FIG. 13B is a plan view of the seed crystal. By making the recess 2d deep in this way, the area where the c-plane is exposed in the seed crystal 2 is eliminated, so that c-plane growth of the crystal from the seed crystal 2 does not occur, and thus the propagation of dislocations from the seed crystal 2 to the upper crystal can be further curtailed. In addition, since the deep depth of the recess 2d makes it easier to form the voids 7.

A mask with ring-shaped (e.g., circular) openings can be used to selectively grow the seed crystal 2 in a ring shape to form the seed crystal 2 shown in FIGS. 13A and 13B.

### Second Modification of the First Embodiment

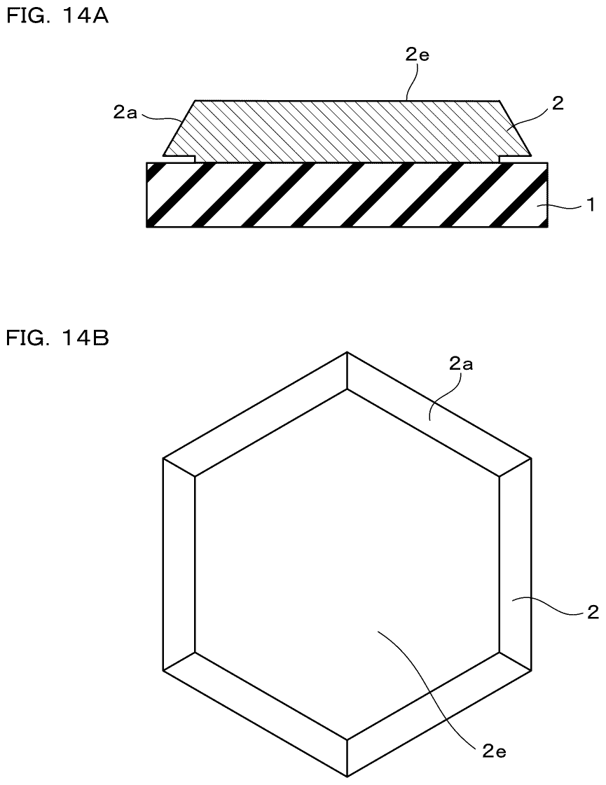

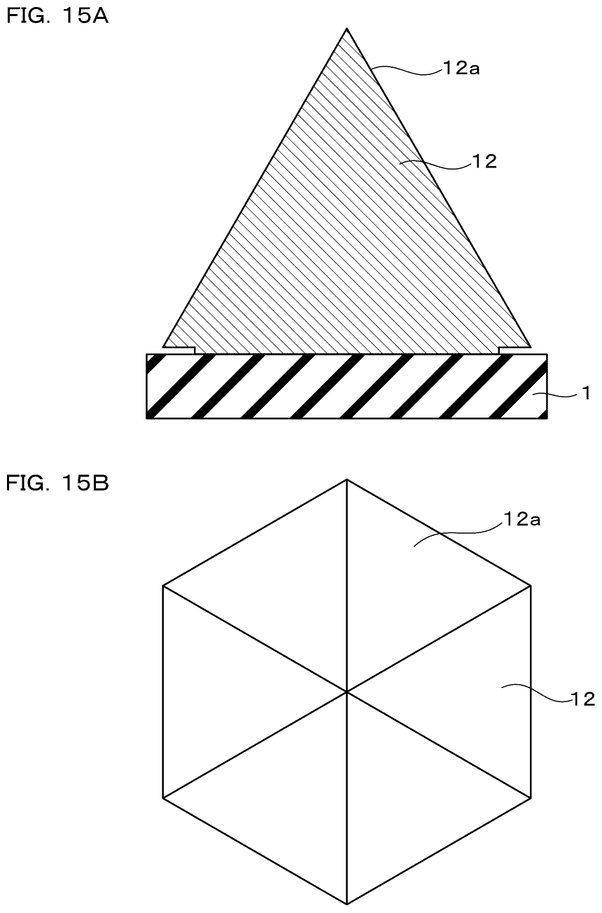

In the first embodiment, the recess 2d was provided in the center of the seed crystal 2, however, as shown in FIGS. 14A and 14B, the truncated regular hexagonal pyramid portion without the recess 2d can be employed. FIGS. 14A and 14B show the shape of the seed crystal 2 in the second modification of the first embodiment. FIG. 14A is a cross-sectional view perpendicular to the principal surface of the substrate, and FIG. 14B is a plan view of the seed crystal. Because the outer peripheral surface of the truncated regular hexagonal pyramid portion of the seed crystal 2 is composed of (10-11) planes, each initial nucleus 3 can be uniformly shaped.

### Third Modification of the First Embodiment

In the first embodiment, the seed crystal may have any shape with an outer peripheral surface composed of the (10-11) planes. For example, as shown in FIGS. 15A and 15B, the truncated regular hexagonal pyramid portion may be replaced with a regular hexagonal pyramid portion shaped in a form of a regular hexagonal pyramid, of which the outer peripheral surface 12a is a (10-11) plane. FIGS. 15A and 15B show the shape of a seed crystal 12 in the third modification of the first embodiment. FIG. 15A is a cross-sectional view perpendicular to the principal surface of the substrate, and FIG. 15B is a plan view of the seed crystal. Because the outer peripheral surface 12a is a (10-11) plane, the initial nucleus 3 can be uniformly shaped. Also, due to having a shape of a pyramid, there is no upper surface. Therefore, it is possible to curtail transfer of dislocations in the seed crystal 2 to the upper part of the seed crystal 2.

### Fourth Modification of the First Embodiment

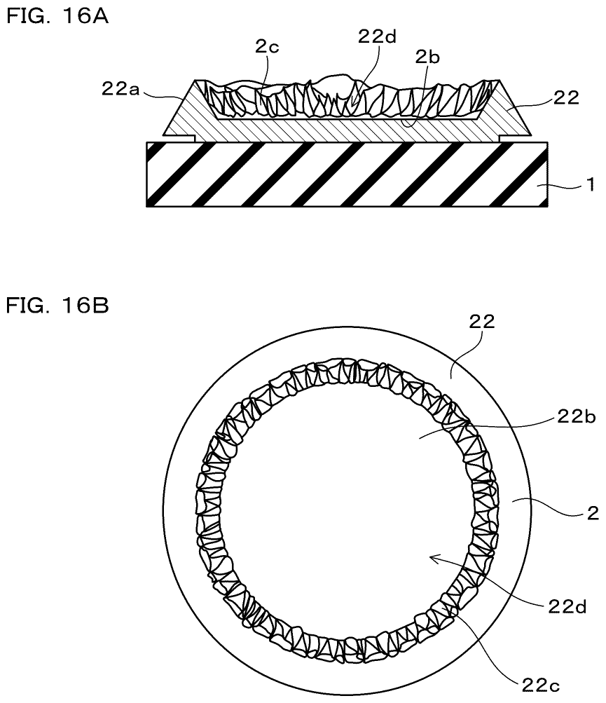

In the first embodiment, the seed crystal 2 may have any shape with a recess in the center. An example is shown in FIGS. 16A and 16B. FIGS. 16A and 16B show the shape of a seed crystal 22 in the fourth modification of the first embodiment. FIG. 16A is a cross-sectional view perpendicular to the principal surface of the substrate, and FIG. 16B is a plan view of the seed crystal. As shown in FIGS. 16A and 16B, the seed crystal 22 in the fourth modification of the first embodiment has a shape in which the truncated regular hexagonal pyramid portion in the first embodiment is replaced with a truncated cone portion shaped in a form of a truncated cone, and has a recess 22d in the center. The bottom surface 22b of the recess 22d is flat. A side surface 22c of the recess 22d has irregularities. Because of having the recess 22d, voids can be formed in the initial nucleus 3 as in the first embodiment. In addition, due to providing the recess 22, there is no c-plane. Therefore, it is possible to curtail transfer of dislocations in the seed crystal 2 to the upper part of the seed crystal 2.

### Fifth Modification of the First Embodiment

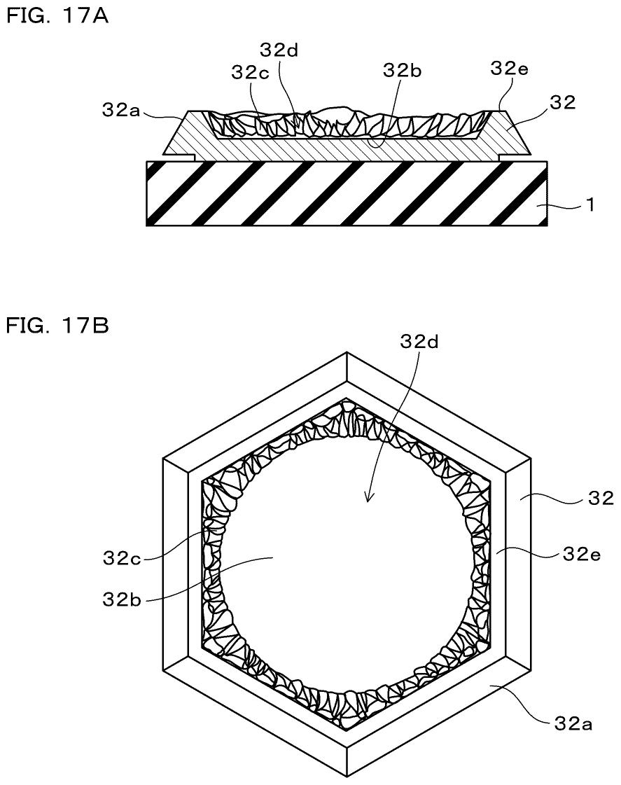

In the first embodiment, the seed crystal 2 has a shape with no upper surface, however, it may have a shape with an upper surface. FIGS. 17A and 17B show the shape of a seed crystal 32 in the fifth modification of the first embodiment. FIG. 17A is a cross-sectional view perpendicular to the principal surface of the substrate, and FIG. 17B is a plan view. of the seed crystal.

As shown in FIGS. 17A and 17B, in the seed crystal 32 in the fifth modification of the first embodiment, the diameter of the recess 32d is small. In a plan view, the outer circumference of the recess 32d is inside the outer circumference of the upper edge of the seed crystal 32. Therefore, a flat top surface 32e is formed in the region from the outer circumference of the recess 32d to the inner circumference of the upper edge of the seed crystal 32. The outer peripheral surface 32a of the truncated regular hexagonal pyramid portion of the seed crystal 32 is a (10-11) plane. The bottom surface 32b of the recess 32d is flat and the side surface 32c has irregularities.

The difference between the fifth modification of the first embodiment and the first embodiment is that the upper surface 32e is formed in the fifth modification. Because the seed crystal 32 has the upper surface 32e thereon, the effect of curtailing upward propagation of the dislocation in the seed crystal 32 is lower than in the first embodiment, however, otherwise the same effect as the seed crystal 2 of the first embodiment can be obtained.

### Other Modification of the First Embodiment

The outer peripheral surface of the seed crystal 2 may have any plane other than the (10-11) planes, however, it is preferably composed of only a plurality of the (10-11) planes and ridge lines. It is also preferable for the outer peripheral surface to have a shape with ridge lines formed between (10-11) planes.

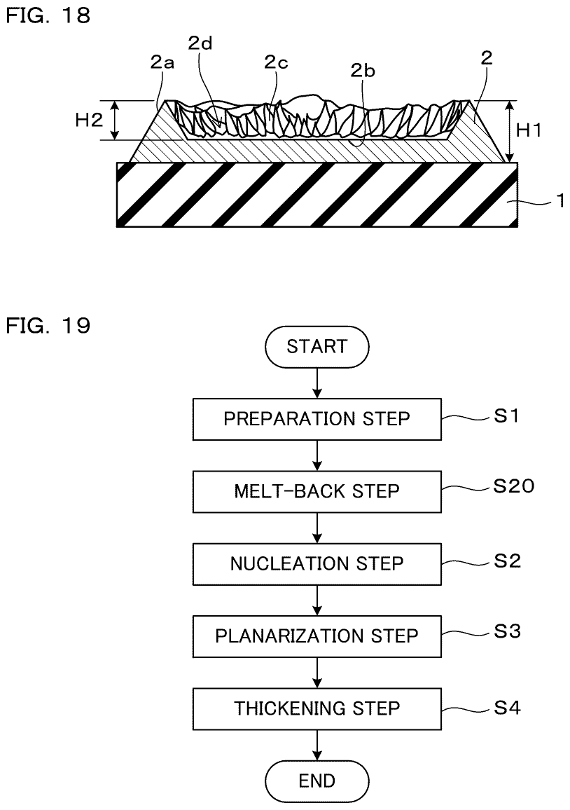

In the first embodiment, the seed substrate 9 includes a disc portion located on the substrate 1 in contact therewith, and a truncated regular hexagonal pyramid portion on the disc portion, however, as shown in FIG. 18, the truncated regular hexagonal pyramid portion may directly contact the substrate 1 without interposing the disc portion therebetween. The same is applied for the first to fifth modifications of the first embodiment.

### Second Embodiment

FIG. 19 is a flowchart showing the production steps of a group III nitride semiconductor in the second embodiment. In the manufacturing method for a group III nitride semiconductor in the second embodiment, a melt-back step S20 is added between the preparation step S1 and the nucleation step S2 in the first embodiment. Other than that, the second embodiment is the same as the first embodiment.

In the melt-back step S20, prior to forming the initial nucleus 3 in the seed crystal 2, the seed substrate 9 is put into the mixed melt 101 for melt-back of the seed crystal 2. The melt-back of the group III nitride semiconductor occurs when a degree of supersaturation of nitrogen in the mixed melt 101 is lower than a degree of supersaturation for crystal growth in the group III nitride semiconductor. Such a state shall include a state in which the nitrogen in the mixed melt 101 is unsaturated.

The method of making the supersaturation of nitrogen in the mixed melt 101 lower than the supersaturation at which the crystal of the group III nitride semiconductors is grown is, for example, as follows.

First, the temperature in the reaction vessel is increased. The higher temperature makes it easier for the nitrogen to dissolve in the mixed melt 101, however, it also increases the dissolution of the group III nitride semiconductor, which makes it more difficult for the group III nitride semiconductors to grow. In other words, the degree of supersaturation of nitrogen becomes lower. For example, the temperature in the reaction vessel is raised 10 to 100° C. higher than the growth temperature in the next step, i.e., the nucleation step S2. Or the temperature in the reaction vessel is set to higher than the growth temperature in the next nucleation step S2 and is set to 800 to 950° C.

Secondly, the pressure in the reaction vessel is set to be low. The higher pressure makes it difficult for nitrogen to dissolve in the mixed melt 101 and the degree of nitrogen supersaturation lowers. For example, the pressure in the reaction vessel is set to be 0.1 to 1.5 MPa lower than the growth temperature in the next step, i.e., the nucleation step S2. Or the pressure in the reaction vessel is set to be lower than the growth pressure of the next nucleation step S2 and is set to 1.5 to 3 MPa.

Third, the oxygen concentration of the mixed melt 101 is increased. The increased oxygen concentration makes it difficult for nitrogen to dissolve in the mixed melt 101, and the degree of nitrogen supersaturation becomes lower. For example, the oxygen concentration of the mixed melt 101 is set to 0.01 to 0.1 mol % higher than that of the mixed melt 101 in the next step, i.e., the nucleation step S2. Or, the oxygen concentration of the mixed melt 101 is set to be higher than the oxygen concentration of the mixed melt 101 in the next nucleation step S2 and is set to 0.01 to 0.1 mol %.

Fourth, the time required for nitrogen to dissolve in the mixed melt 101 after the inside of the reaction vessel reaches the crystal growth temperature and pressure is shortened. When this time is shortened, the amount of nitrogen dissolved in the mixed melt 101 is also reduced, resulting in a lower degree of nitrogen supersaturation.

Fifth, nitrogen supply to the reaction vessel is reduced. When the nitrogen supply is reduced, the amount of nitrogen dissolved in the mixed melt 101 is also reduced, resulting in a lower degree of nitrogen supersaturation.

Sixth, the seed substrate 9 in the mixed melt 101 is placed deeper from the liquid surface. The nitrogen concentration in the mixed melt 101 becomes higher the closer it is to the liquid surface, and becomes lower the farther it is from the liquid surface. Therefore, by placing the seed substrate 9 at a deeper position from the liquid surface, the mixed melt 101 with a lower nitrogen supersaturation can be brought into contact with the seed crystal 2.

Next, the changes in the shape of the seed crystal 2 due to melt-back are explained with reference to FIGS. 3, 13A, 13B, 20, and 21.

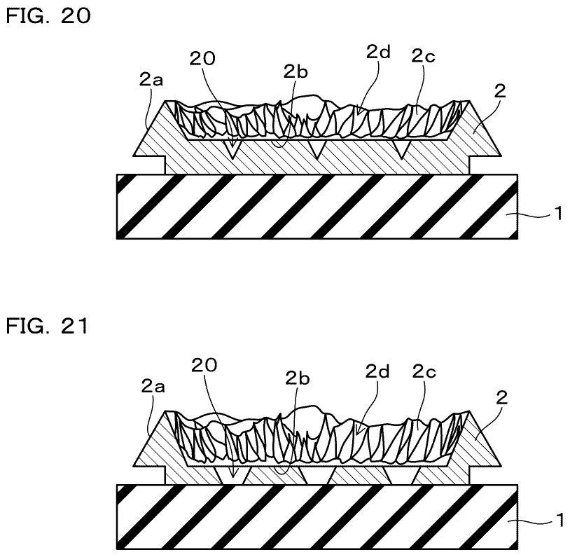

Before melt-back of the seed crystal 2, the seed crystal 2 has the same shape as that in the first embodiment as shown in FIG. 3. The rate of melt-back in a group III nitride semiconductor varies with the plane orientation. Melt-back easily progresses on the c-plane and does not progress so much on the (10-11) plane. Therefore, the bottom surface 2b of the recess 2d of the seed crystal 2 preferentially melts back, and the outer peripheral surface 2a of the seed crystal 2 hardly melts back. In particular, melt-back progresses quickly at the location of through-through dislocation on the bottom surface 2b. Therefore, as shown in FIG. 20, pits 20 are generated at the location of through-through dislocation on the bottom surface 2b. The pits 20 are a concave portion with a V-shape in the cross section perpendicular to the principal surface of the substrate 1. In other words, the side surface of the pit 20 is inclined with respect to the principal surface of the substrate 1.

As the melt-back progresses further, the height from the surface of substrate 1 to the bottom surface 2b decreases. In addition, the melt-back progresses on the side surface of the pit 20 while maintaining the inclination of the side surface, thus, the diameter of the pits 20 increases. As the melt-back in the side surface of each pit 20 progresses still further, the pit 20 becomes trapezoidal in shape in the cross section perpendicular to the principal surface of the substrate 1, and the surface of substrate 1 is exposed to the bottom surface of the pit 20, as shown in FIG. 21.

As the melt-back progresses further, the diameter of the pits 20 increases and the pits 20 adjacent to each other coalesce with each other. And finally, the group III nitride semiconductor that lies between the surface of the substrate 1 and the bottom surface 2b of the recess 2d entirely disappears due to melt-back. As a result, the surface of the substrate 1 is exposed at the entire bottom surface 2b of the recess 2d as shown in FIGS. 13A and 13B. The seed crystal 2 has no c-plane. In this way, the surface of the substrate 1 can be easily exposed to the bottom surface 2b of the recess 2d by melt-back of the seed crystal 2 in which the surface of the substrate 1 is not exposed to the bottom surface 2d of the recess 2d.

In some cases, melt-back is caused to the side surface 2c of the recess 2d with the lapse of a sufficiently long time. The irregularities on the side surface 2c of the recess 2d are reduced by melt-back of the side surface 2c, and the side surface 2c gradually becomes smooth.

Once the surface of the substrate 1 is exposed to the bottom surface 2b of the recess 2d as shown in FIGS. 13A and 13B, the supersaturation degree of nitrogen in the mixed melt 101 is made higher. Then, the supersaturation degree of nitrogen is set higher than the supersaturation degree at the crystal growth in a group III nitride semiconductor. In such a way, the nucleation step S2 is performed. The following step is the same as in the first embodiment.

When seed crystal 2 does not melt back, the c-plane of the group III nitride semiconductor is exposed to the bottom surface 2b of the recess 2d as shown in FIG. 3. If the c-plane is present in the seed crystal 2 in this way, dislocations in the seed crystal 2 may propagate to the group III nitride semiconductor crystal on the c-plane. In contrast, in the second embodiment, the substrate 1 is exposed to the bottom surface 2b of the recess 2d of the seed crystal 2 by melt-back, so there is no c-plane in the seed crystal 2. Therefore, the upward propagation of dislocations in the seed crystal 2 can be curtailed.

Because the substrate 1 is exposed to the bottom surface 2b of the recess 2d of the seed crystal 2, the contact area between the seed crystal 2 and the substrate 1 is reduced. Therefore, the substrate 1 can be easily separated after completion of the crystal growth of the group III nitride semiconductor.

### First Modification of the Second Embodiment

In the second embodiment, melt-back is caused until the substrate 1 is exposed to the entire bottom surface 2b of the recess 2d, however, the melt-back may be performed to the extent that the substrate 1 is not exposed and transition to the nucleation step S2 at the stage is possible. In this case, the thickness from the surface of the substrate 1 to the bottom surface 2b had better be as thin as possible. Such a configuration makes it easy to form voids upward the bottom surface 2b, thus the upward propagation of dislocations in the seed crystal 2 can be further curtailed.

### Second Modification of the Second Embodiment

At the stage of exposing the substrate 1 to part of the bottom surface 2b through the pit 20 as shown in FIG. 21, the production step may shift to the nucleation step S2. Because of reduction in the c-plane area of the seed crystal 2, upward propagation of the dislocations in the seed crystal 2 can be further curtailed. However, from the viewpoint of further curtailing the upward propagation, the shift to the nucleation step S2 is preferably carried out after the substrate 1 is exposed to the whole of the bottom surface 2b as in the second embodiment.

### Third Modification of the Second Embodiment

The shape of the seed crystal 2 before the melt-back step S20 is not limited to the shape shown in FIG. 3. Any shape having a recess in the center, the depth of which does not reach the substrate 1 may be allowed. The second embodiment can be applied to the seed crystal 2 with such a shape as shown in FIGS. 16A to 18, for example. The shape preferably has no upper surface as shown in FIGS. 3, 16A, 16B, and 18.

What is claimed is:

1. A method for manufacturing a group III nitride semiconductor, the method comprising:
a crystal growing step of growing the group III nitride semiconductor on a seed substrate by supplying a gas containing nitrogen into a mixed melt in which a group III metal and a flux are mixed, wherein
the seed substrate includes a substrate and a plurality of seed crystals provided on the substrate and composed of the group III nitride semiconductor, and
the seed crystals each include a (10-11) plane on an outer peripheral surface thereof.

2. The method according to claim 1, wherein the outer peripheral surface of the seed crystal has a plurality of the (10-11) planes and a ridge line formed between the (10-11) planes adjacent to each other.

3. The method according to claim 2, wherein the outer peripheral surface of the seed crystal is composed of only the (10-11) planes and the ridge lines.

4. The method according to claim 1, wherein a height of the seed crystal is 0.01 times or more and 0.6 times or less of a diameter of the seed crystal in a plan view.

5. The method according to claim 1, wherein the height of the seed crystal is 30 μm or more.

6. The method according to claim 1, wherein the diameter of the seed crystal is 10 μm or more and 500 μm or less in a plan view.

7. The method according to claim 1, wherein the seed crystal has a truncated regular hexagonal pyramid portion shaped in a form of a truncated regular hexagonal pyramid.

8. The method according to claim 7, wherein the seed substrate includes a disk portion having a diameter smaller than a diameter of the truncated regular hexagonal pyramid portion, the disk portion being located between the substrate and the truncated regular hexagonal pyramid portion.

9. The method according to claim 1, wherein the seed crystals each have a recess at a center thereof.

10. The method according to claim 9, wherein the recess has a depth reaching the substrate.

11. The method according to claim 9, wherein a diameter of the recess is set such that the seed crystals each have a shape with no upper surface.

12. The method according to claim 9, wherein the recess has irregularities on a side surface thereof.

13. The method according to claim 9, wherein a mask with an opening is formed on the substrate to selectively grow the group III nitride semiconductor through the opening, thereby forming the seed crystals.

14. The method according to claim 9, wherein the recess of the seed crystal has a depth not reaching the substrate, and
the method further comprises a melt-back step prior to the crystal growing step, in which a degree of supersaturation of nitrogen in the mixed melt is set lower compared to a degree of supersaturation for crystal growth in the group III nitride semiconductor, and the seed substrate is poured into the mixed melt thus prepared to thereby cause melt-back to a bottom surface of the recess of each seed crystal.

15. The method according to claim 14, wherein in the melt-back step, melt-back is caused to at least a partial region on the bottom surface of the recess of the seed crystal to an extent of exposing the substrate.

16. The method according to claim 15, wherein in the melt-back step, the melt-back is caused to a whole region on the bottom surface of the recess of the seed crystal to an extent of exposing the substrate.

17. The method according to claim 14, wherein in the melt-back step, a plurality of pits is formed on the bottom surface of the recess of the seed crystal, and the substrate is exposed to the bottom surface of the pits.
